(19) United States
(12) Patent Application Publication
(10) Pub. No.: US 2023/0356999 A1
(43) Pub. Date: Nov. 9, 2023

(54) MICROELECTROMECHANICAL DEVICE AND PROCESS FOR MANUFACTURING A MICROELECTROMECHANICAL DEVICE

(71) Applicant: STMICROELECTRONICS S.r.l., Agrate Brianza (IT)

(72) Inventors: Filippo DANIELE, Milano (IT); Lorenzo BALDO, Bareggio (IT); Davide MAERNA, Arluno (IT); Enri DUQI, Milan (IT)

(73) Assignee: STMICROELECTRONICS S.r.l., Agrate Brianza (IT)

(21) Appl. No.: 18/308,562

(22) Filed: Apr. 27, 2023

(30) Foreign Application Priority Data
May 9, 2022 (IT) 102022000009488

(51) Int. Cl. B81B 7/00

(52) U.S. Cl. CPC B81B 7/0048; B81B 7/008

(57) ABSTRACT

A microelectromechanical device includes a support structure, a microelectromechanical system die, incorporating a microstructure and a connection structure between the microelectromechanical system die and the support structure. The connection structure includes a spacer structure, joined to the support structure, and a film applied to one face of the spacer structure opposite to the support structure. The spacer structure laterally delimits at least in part a cavity and the film extends on the cavity, at a distance from the support structure. The microelectromechanical system die is joined to the film on the cavity.

### BACKGROUND

### Technical Field

The present disclosure relates to a microelectromechanical device and to a process for manufacturing a microelectromechanical device.

### Description of the Related Art

As is known, some microelectromechanical devices are particularly sensitive to stresses which may cause deformations even minor ones. For example, different membrane sensors and transducers, such as pressure sensors and electroacoustic transducers, are affected by the mechanical stresses conveyed by the package wherein they are accommodated. The stresses may have various origins. Among the most frequent, the thermomechanical stresses resulting from exposure to strong temperature variations or from the presence of materials with different thermal expansion coefficients and the stresses from residual internal strains after manufacturing may be mentioned. As mentioned, mechanical stresses of this kind cause temporary or permanent deformations that affect critical elements of the sensors, for example membranes or piezoelectric transduction structures, and may alter the performances. In some cases, the error due to the stresses from the package may not be compatible with the required resolution and accuracy.

In order to overcome the problems caused by the mechanical stresses conveyed by the package, it has been proposed to interpose soft glue layers between the die containing the microelectromechanical structure of the device and the support structure of this die (generally a polymeric substrate or a printed circuit board; or an additional die, possibly mounted on a polymeric substrate or a printed circuit board). In this manner, a certain degree of decoupling is obtained.

However, the above may not be entirely satisfactory. In fact, a considerable thickness of the soft glue layer may be required to obtain the desired degree of decoupling. Yet, providing a soft glue layer of sufficient thickness may be difficult. Furthermore, during the steps of placing the microelectromechanical devices, the soft glue layer, beyond a certain thickness, does not offer a sufficiently stiff support and may make bonding difficult, reducing the yield of the manufacturing processes. Conversely, a reduced thickness may not achieve a suitable degree of mechanical decoupling and therefore may not represent an acceptable solution.

### BRIEF SUMMARY

The present disclosure is directed to providing a microelectromechanical device and a process for manufacturing a microelectromechanical device which allow the limitations described to be overcome or at least mitigated.

At least one embodiment of a device of the present disclosure may be summarized as including: a substrate including a first surface; a control die on the first surface of the substrate, the control die including a second surface facing away from the substrate; a suspended support structure suspended over the second surface of the control die, the suspended support structure including an outer frame and one or more openings that are surrounded by the outer frame; and a microelectromechanical system (MEMS) die coupled to the outer frame of the suspended support structure.

### BRIEF DESCRIPTION OF THE SEVERAL VIEWS OF THE DRAWINGS

For a better understanding of the disclosure, some embodiments thereof will now be described, purely by way of non-limiting example and with reference to the attached drawings, wherein:

FIG. 1 is a top plan view of a microelectromechanical device according to an embodiment of the present disclosure;

FIG. 2 is a cross-section through the microelectromechanical device of FIG. 1, taken along line II-II of FIG. 1;

FIG. 3 is a cross-section through the microelectromechanical device of FIG. 1, taken along line III-III of FIG. 1;

FIG. 4 is a cross-section through a microelectromechanical device according to a different embodiment of the present disclosure;

FIG. 5 is a top plan view of a microelectromechanical device according to another embodiment of the present disclosure;

FIG. 6 is a cross-section through the microelectromechanical device of FIG. 5, taken along line VI-VI of FIG. 5;

FIG. 7 is a cross-section through a microelectromechanical device according to a further embodiment of the present disclosure;

FIG. 8 is a cross-section through a microelectromechanical device according to a different embodiment of the present disclosure;

FIGS. 9-11 illustrate successive steps of a process for manufacturing a microelectromechanical device according to an embodiment of the present disclosure; and

FIG. 12 is a simplified block diagram of an electronic system incorporating a microelectromechanical device according to the present disclosure.

### DETAILED DESCRIPTION

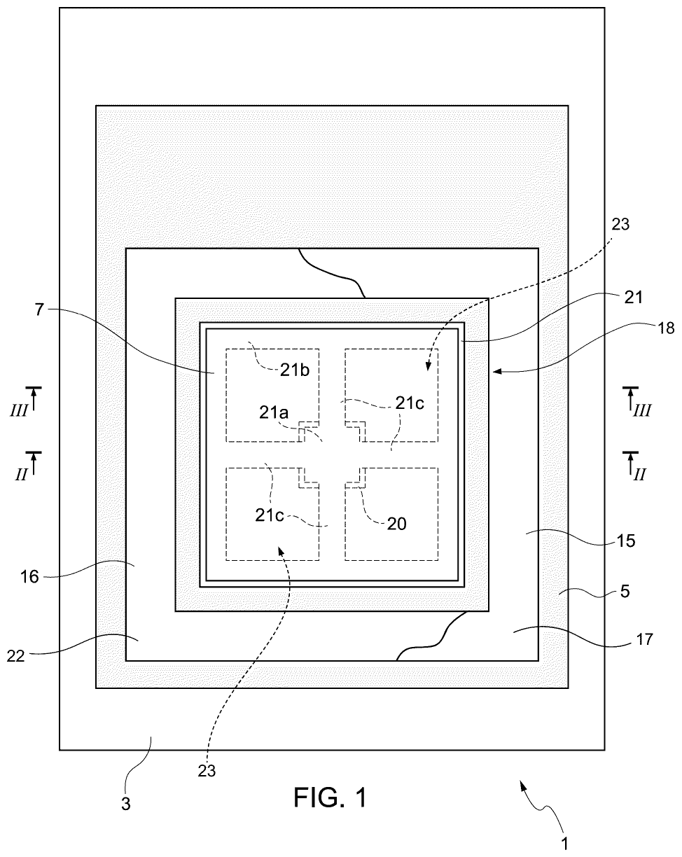

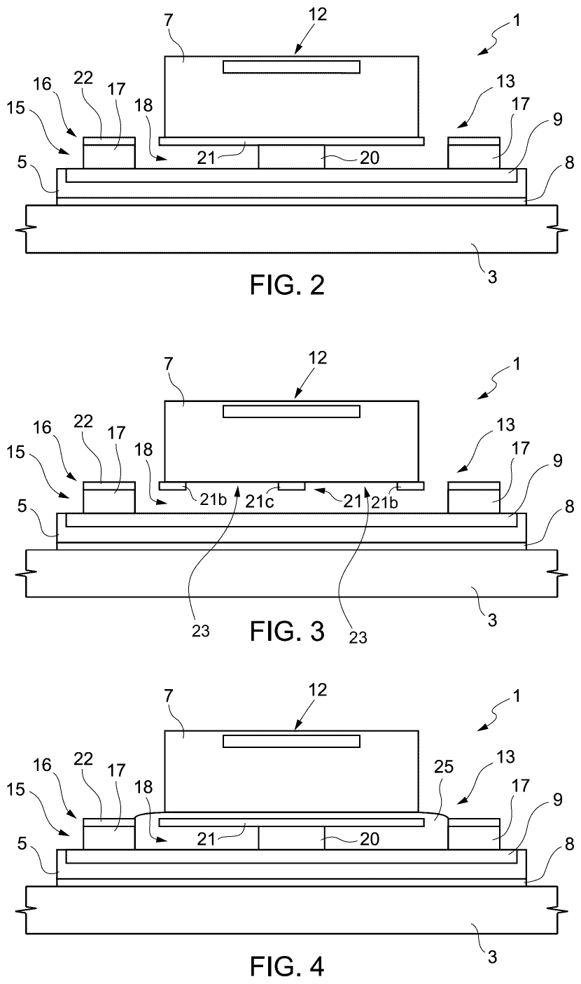

With reference to FIGS. 1-3, a microelectromechanical device or MEMS (Micro-Electro-Mechanical System) is indicated as a whole with the number 1 and comprises a package, whereof only a substrate 3, a control die 5 and a microelectromechanical system die or, as will be indicated below for simplicity, MEMS die 7 are shown for simplicity.

The substrate 3 has a support function and may be, for example, a polymeric material layer or a printed circuit board (PCB).

The control die 5 is joined to the substrate 3 by an adhesive layer 8 and incorporates a dedicated control circuit or ASIC (Application Specific Integrated Circuit) 9, not illustrated herein in detail. The control die 5, in particular the dedicated control circuit 9, is functionally coupled to the MEMS die 7 to perform the operations wherefore the MEMS die 7 is designed (in general, the conversion of sensed physical quantities into electrical signals and/or the conversion of electrical signals into physical quantities). The connection between the dedicated control circuit 9 and the MEMS die 7, may be obtained by wire bonding and is not illustrated herein for simplicity.

The MEMS die 7 incorporates a microelectromechanical structure 12, for example a membrane, and for example operates as a piezoelectric, piezoresistive or capacitive pressure sensor. However, the disclosure should not be construed as limited to these examples, but may be generally exploited when desired for any type of microelectromechanical device, including, in particular, electroacoustic transducers (microphones and speakers).

The MEMS die 7 is joined to a support structure which, in the embodiment of FIGS. 1-3, is defined by the substrate 3 and the control die 5. In particular, the MEMS die 7 is joined to a face of the control die 5 opposite to the substrate 3. In other embodiments, not shown, the MEMS die might be joined directly to the substrate 3 or to a different intermediate substrate or yet the support structure may be defined by the sole control die 5.

In order to join the MEMS die 7 to the support structure, the microelectromechanical device 1 comprises a connection structure 13. In turn, the connection structure 13 comprises a spacer structure 15, formed on the control die 5, and a film 16 applied to one face of the spacer structure 15 opposite to the control die 5. The film 16 may fully cover the one face of the spacer structure.

The spacer structure 15 is formed for example by a resist layer deposited on the control die 5 and subsequently patterned. In the embodiment of FIGS. 1-3, the spacer structure 15 comprises a first portion, forming an outer frame 17 which laterally delimits a cavity 18, and a second portion, which defines an anchor 20 inside the cavity 18. The cavity 18 is further delimited by the face of the control die 5 on which the spacer structure 15 is formed. In plan, the frame 17 and the anchor 20 may have a polygonal shape, for example square or rectangular. The frame 17 may not be continuous in some embodiments. In these cases, the cavity 18 is laterally delimited only in part and may communicate with the outside. The cavity 18 has greater dimensions (width and length) with respect to corresponding dimensions of the MEMS die 7.

In the cases in which the frame 17 is not continuous, the frame 17 may instead be a plurality of discrete portions that are discrete and separate from each other and extend around the anchor 20 such that the cavity 18 is partially delimited by the plurality of discrete portions. Adjacent pairs of the plurality of discrete portions of the frame 17 may be separated from each other by a corresponding opening of a plurality of openings or trenches.

As shown in FIG. 1, a portion of the film 16 is hidden at the right hand-side of FIG. 1 such that the spacer structure 15 covered by the film 16 is readily visible in FIG. 1.

The film 16 in one embodiment is obtained from a dry resist sheet laminated on the spacer structure 15 and subsequently patterned. In particular, the film 16 forms a platform 21 bonded to the anchor 20 and maintained by the same anchor 20 at least partially suspended on the cavity 18 at a distance from the control die 5. An outer portion 22 of the film 16 may be present on the frame 17 of the spacer structure 15.

In the embodiment of FIGS. 1-3, the platform 21 is centrally supported by the anchor 20. In detail, the platform 21 comprises a central anchor portion 21a supported by the anchor 20, an outer frame 21b and arms 21c projecting from the anchor 20 and connecting the central anchor portion 21b to the outer frame 21b. The outer frame 21b in one embodiment is quadrangular and defines an outer shape of the platform 21. The anchor 20, also quadrangular, has dimensions not greater than 30% of corresponding dimensions of the platform 21. In practice, each side of the anchor 20 is not greater than 30% of a corresponding side of the outer frame 21b of the platform 21. The arms 21c have a width comprised between 5% and 15% of a maximum dimension of the platform 21, for example 10%.

As shown in FIG. 1, the anchor 20 extends laterally outward from the central anchor portion 21a, and is larger than the central anchor portion 21a. The anchor 20 being larger than the central anchor portion 21a is shown by L-shaped features at respective corners of the central anchor portion 21a.

The MEMS die 7 is joined to the platform 21, more precisely to the outer frame 21b. Like the platform 21, the MEMS die 7 is also centrally supported by the sole anchor 20 and projects laterally, remaining suspended on the cavity 18. Since the dimensions (width and length) of the cavity 18 are greater than the corresponding dimensions of the MEMS die 7, the MEMS die may be arranged so that it is not superimposed on the frame 17 of the spacer structure 15.

In the embodiment described, the mechanical connection between the MEMS die 7 and the support structure, in this case formed by the substrate 3 and the control die 5, is limited to the anchor 20. Since the dimensions of the anchor 20 are small and significantly smaller with respect to the dimensions of the MEMS die 7, the deformations and stresses whereto the support structure is subject are not conveyed, or at least are conveyed to a negligible extent, to the MEMS die 7. Consequently, the operation of the MEMS die 7 is not affected by the effects of the deformations and the stresses induced by outer factors, for example of thermomechanical origin, to the advantage of the accuracy.

The dimensions of the platform 21 may be conveniently chosen so that the placing of the MEMS die 7 may be carried out accurately and without difficulty.

As shown in FIGS. 1 and 3, one or more openings 23 may be present within the platform 21. As shown in FIG. 1, the one or more openings 23 have a square-like or a rectangular-like shape and are positioned around the central anchor portion 21a.

In one embodiment (FIG. 4), the cavity 18 is filled with a sealing gel 25, for example potting gel. The sealing gel 25 makes the cavity 18 impermeable and protects the dedicated control circuit 9 from humidity. The sealing gel may cover the platform 21. In this case, a thin gel layer may be interposed between the platform 21 and the MEMS die 7.

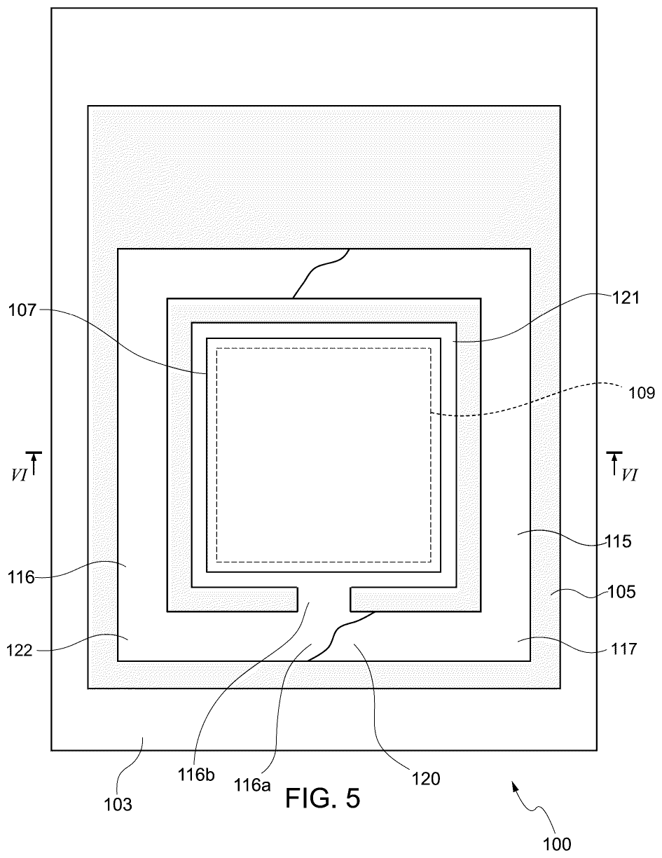

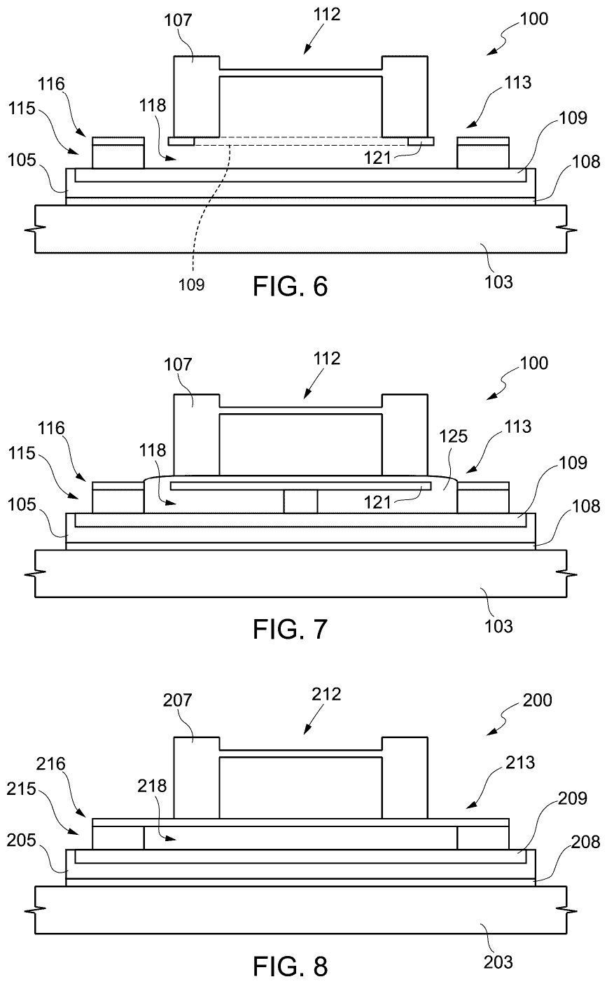

According to an embodiment of the disclosure, illustrated in FIGS. 5 and 6, a microelectromechanical device 100 comprises a package, whereof only a substrate 103, a control die 105 and a MEMS die 107 are shown for simplicity. The substrate 103 and the control die 5 are joined to each other, for example by an adhesive layer 108, and form a support structure for the MEMS die 107, substantially as already described.

The MEMS die 107 incorporates a microelectromechanical structure 112, here again of the membrane type, and for example operates as an electroacoustic transducer (microphone or loudspeaker).

The microelectromechanical device 100 comprises a connection structure 113 which joins the MEMS die 107 to the support structure, in particular to the control die 105. In turn, the connection structure 113 comprises a spacer structure 115, formed on the control die 105, and a film 116 applied to one face of the spacer structure 115 opposite to the control die 105. The spacer structure 115 forming a frame which laterally delimits a cavity 118, having greater dimensions (width and length) with respect to corresponding dimensions of the MEMS die 107.

The film 116 is obtained from a dry resist sheet laminated on the spacer structure 115 and subsequently patterned. In particular, the film 116 forms a platform 121 bonded to an anchor 120, defined by a portion, for example one side, of the spacer structure 115. The platform 121 is supported laterally by the anchor 120 and maintained by the same anchor 120 at least partially suspended on the cavity 118 at a distance from the control die 105. More precisely, the film 116 comprises an anchor portion 116a supported by the anchor 120 and an arm 116b which connects the anchor portion 116a to an outer side of the platform 121, which is frame-shaped and has a central opening 109.

The MEMS die 107 is joined to the platform 121 and is therefore supported laterally with respect to the anchor 120, above the cavity 118. The support for the MEMS die 107 in this case is provided exclusively by the platform 121 and the arm 116b which connects the platform 121 to the anchor portion 116 of the film 116. The width and length of the arm 116b, in particular, may be selected so that the same arm 116b has sufficient stiffness to support the MEMS die 107.

The central opening 109 present within the platform 121 is surrounded by the platform 121. The central opening 109 is represented by the dotted lines as shown in FIGS. 5 and 6, respectively. As shown in FIG. 5, the central opening 109 has a square or rectangular shape. As shown in FIG. 5, a portion of the film 116 is hidden such that a portion of the spacer structure 115 covered by the film 116 is readily visible in FIG. 5.

In this case, the MEMS die 107 is completely insensitive to the deformations of the support structure and the functioning is not affected, in particular, by the thermomechanical stresses and residual stresses that might be conveyed through the support structure. The platform 121, in fact, is connected to the anchor 120 only through the arm 116b and the MEMS die 107 does not overlap at any point on the spacer structure 115. The deformations of the support structure may at most slightly modify the relative position of the platform 121 and the MEMS die 107 with respect to the same support structure, but the strains are not conveyed. 10 In the embodiment of FIG. 5, the spacer structure 115 comprises an outer frame 117 which laterally delimits the cavity 118. The cavity 118 is further delimited by the face of the control die 105 on which the spacer structure 15 is formed. In plan, the frame 117 may have a polygonal shape, for example square or rectangular. The frame 117 may not be continuous in some embodiments. In these cases, the cavity 118 is laterally delimited only in part and may communicate with the outside. The cavity 118 has greater dimensions (width and length) with respect to corresponding dimensions of the MEMS die 107.

In the cases in which the frame 117 is not continuous, the frame 117 may instead be a plurality of discrete portions that are discrete and separate from each other and extend around the cavity 118 such that the cavity 118 is partially delimited by the plurality of discrete portions. Adjacent pairs of the plurality of discrete portions of the frame 117 may be separated from each other by a corresponding opening of a plurality of openings or trenches.

An outer portion 122 of the film 116 may be present on the frame 117 of the spacer structure 115.

Also in this case, the cavity 118 may be filled with a sealing gel 125, as shown in the embodiment of FIG. 7.

With reference to FIG. 8, in one embodiment of the present disclosure a microelectromechanical device 200 may comprise a package with a substrate 203, a control die 205, a MEMS die 207, incorporating a microelectromechanical structure 212, and a connection structure 213 which joins the MEMS die 207 to the support structure formed by the substrate 203 and the control die 205 joined to each other. The connection structure 213 comprises a frame-shaped spacer structure 215, formed on the control die 205 and delimiting a cavity 218, and a film 216 applied to one face of the spacer structure 215 opposite to the control die 205. The film 216 in this case is continuous and closes the cavity 218, which has a length and width greater than the length and width of the MEMS die 207.

The MEMS die 207 is joined to the film 216 above the cavity 218 and is therefore suspended without overlapping the spacer structure 215.

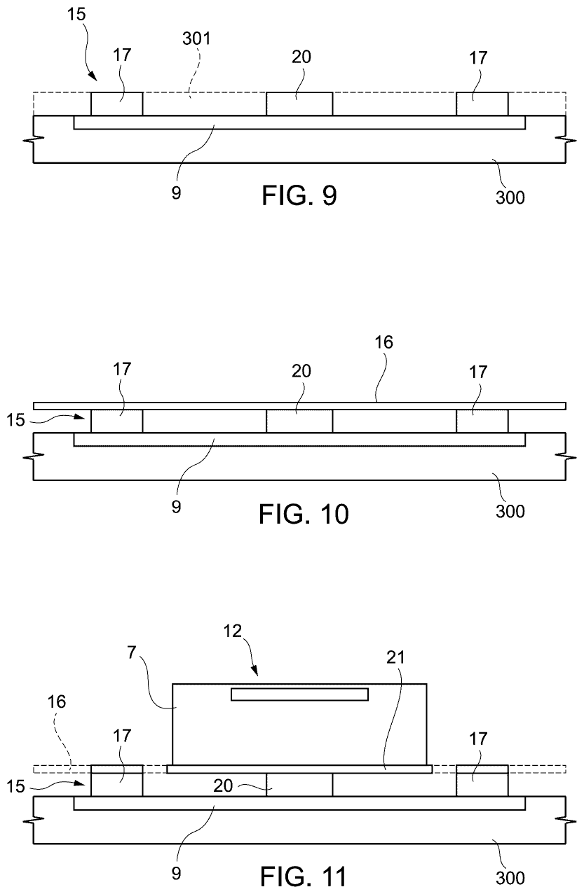

FIGS. 9-11 summarily show an example of a process for manufacturing a microelectromechanical device according to the disclosure, in particular the microelectromechanical device of FIGS. 1-3.

In a semiconductor wafer 300 the dedicated control circuit 9 is initially provided, then a spacer layer 301 of resist is deposited and patterned by a first photolithographic process to form the spacer structure 15, including the anchor 20.

The film 16 (FIG. 10) of dry resist is laminated on the wafer 300 and adheres to the spacer structure 15 which projects.

The film 16 is defined with a second photolithographic process to form the platform 21 (FIG. 11) and the MEMS die 7, provided separately from a different semiconductor wafer not shown, is joined to the platform 21. The wafer 300 is then diced and the composed dice obtained are joined to respective substrates 3, to form the microelectromechanical device 1 of FIGS. 1-3.

Alternatively, before joining the MEMS die 7, the cavity is filled with the sealing gel 25, to obtain the structure of FIG. 4.

The structures of FIGS. 5-6 and FIG. 7 may be provided with the same process, simply by using photolithographic masks with the desired pattern.

In order to provide the microelectromechanical device 200 of FIG. 8, the MEMS die 207 is joined to the film 216 without having carried out the second photolithographic process.

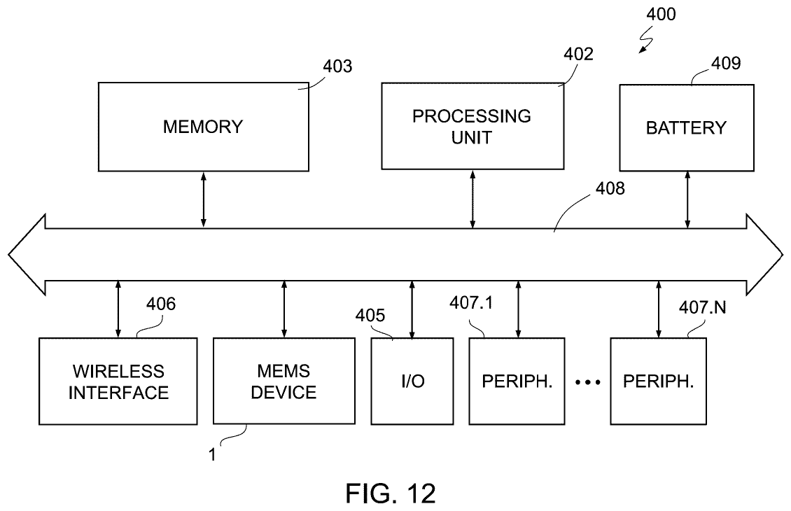

FIG. 12 shows an electronic system 400 which may be of any type, in particular, but not limited to, a wearable device, such as a watch, a bracelet or a “smart” band; a computer, such as a mainframe, a personal computer, a laptop, or a tablet; a smartphone; a digital music player, a digital camera or any other device for processing, storing, transmitting or receiving information. The electronic system 400 may be a general purpose or device-embedded processing system, an equipment or a further system.

The electronic system 400 comprises a processing unit 402, memory devices 403, a microelectromechanical device according to the disclosure, for example the microelectromechanical device (pressure sensor) 1 of FIG. 1, and may also be provided with input/output (I/O) devices 405 (for example a keyboard, a pointer or a touch screen), a wireless interface 406, peripherals 407.1, . . . , 407.N and possibly further auxiliary devices, not shown here. The components of the electronic system 400 may be coupled in communication with each other directly and/or indirectly through a bus 408. The electronic system 400 may further comprise a battery 409. It should be noted that the scope of the present disclosure is not limited to embodiments necessarily having one or all of the listed devices.

The processing unit 402 may comprise, for example, one or more microprocessors, microcontrollers and the like, according to the design preferences.

The memory devices 403 may comprise volatile memory devices and non-volatile memory devices of various kinds, for example SRAM and/or DRAM memories for volatile memories and solid-state memories, magnetic disks and/or optical disks for non-volatile memories.

Finally, it is apparent that modifications and variations may be made to the described microelectromechanical device, without departing from the scope of the present disclosure, as defined in the attached claims.

In particular, it is understood that all the connection structures described may be used with microelectromechanical devices of any type, both of membrane type and other types, according to the design preferences.

The support structure may be of any suitable type in addition to those described. For example, the MEMS die may be joined directly to a portion of the package, without the interposition of the control die and any suitable part of the packaging may function as a support structure. Conversely, other components may be interposed between the MEMS die and the packaging or the control die (for example, another die).

A microelectromechanical may be summarized as including a support structure (3, 5; 103, 105; 203, 205); a microelectromechanical system die (7; 107; 207) incorporating a microstructure (12; 112; 212); and a connection structure (13; 113; 213) between the microelectromechanical system die (7; 107; 207) and the support structure (3, 5; 103, 105; 203, 205); wherein the connection structure (13; 113; 213) includes a spacer structure (15; 115; 215), joined to the support structure (3, 5; 103, 105; 203, 205), and a film (16; 116; 216) applied to a face of the spacer structure (15; 115; 215) opposite to the support structure (3, 5; 103, 105; 203, 205); wherein the spacer structure (15; 115; 215) laterally delimits at least in part a cavity (18; 118; 218) and the film (16; 116; 216) extends on the cavity (18; 118; 218), at a distance from the support structure (3, 5; 103, 105; 203, 205); and wherein the microelectromechanical system die (7; 107; 207) is joined to the film (16; 116; 216) on the cavity (18; 118; 218).

The film (16; 116; 216) may be of dry resist.

The microelectromechanical system die (7; 107; 207) may extend on the cavity (18; 118; 218) without overlapping the spacer structure (15; 115; 215) around the cavity (18; 118; 218).

The film (16; 116) may define a platform (21; 121) extending on the cavity (18; 118) and the microelectromechanical system die (7; 107) may be joined to the platform (21; 121).

The cavity (18; 118) may be filled with a sealing gel (25; 125).

The platform (21; 121) may be maintained suspended by an anchor (20; 120).

The anchor (20; 120) may be defined by an anchor portion (20; 120) of the spacer structure (15; 115).

The platform (21) may be centrally supported by the anchor (20).

The platform (21) may include a central anchor portion (21a) supported by the anchor (20), an outer frame (21b) and arms (21c) may project from the anchor (20; 120) and connect the central anchor portion (21a) to the outer frame (21b).

The platform (121) may be supported laterally by the anchor (120).

The film (116) may include an anchor portion (116a) supported by the anchor (120) and at least one arm (116b) may connect the anchor portion (116a) to the platform (121).

The platform (121) may be frame-shaped and an outer side of the platform (121) may be connected to the anchor portion (116a) of the film (116) by the at least one arm (116b).

The support structure (3, 5; 103, 105; 203, 205) may include a substrate (3; 103; 203) and a control die (5; 105; 205), joined to the substrate and functionally coupled to the microstructure (12; 112; 212) of the microelectromechanical system die (7; 107; 207) and the connection structure (13; 113; 213) may join the microelectromechanical system die (7; 107; 207) to the control die (5; 105; 205).

An electronic system may be summarized as including a processing unit (402) and a microelectromechanical device (1).

The microelectromechanical device (1) may be a membrane device, in particular one of a pressure sensor and an electroacoustic transducer.

A process for manufacturing a microelectromechanical device may be summarized as including depositing a spacer layer (301) of resist on a semiconductor wafer (300); from the spacer layer (301), forming a spacer structure (15) laterally delimiting at least in part a cavity (18); applying a film (16) to the semiconductor wafer (300), so that it adheres to the spacer structure (15); and joining a microelectromechanical system die (7) incorporating a microelectromechanical structure to the film (16) on the cavity (18).

The film (16) may be of dry resist and may be defined with a photolithographic process before joining the microelectromechanical system die (7).

The various embodiments described above can be combined to provide further embodiments. Aspects of the embodiments can be modified, if necessary to employ concepts of the various patents, applications and publications to provide yet further embodiments.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A device, comprising:
a support structure;
a microelectromechanical system (MEMS) die including a microstructure; and
a connection structure between the microelectromechanical system die and the support structure, the connection structure includes:
a spacer structure coupled to the support structure; and
a film on a face of the spacer structure opposite to the support structure, the film is spaced apart from the support structure by the spacer structure, and the film is coupled to the microelectromechanical system die,
a cavity at least in part delimited by the spacer structure.

2. The device according to claim 1, wherein the film is of dry resist.

3. The device according to claim 1, wherein the microelectromechanical system die overlaps the cavity without overlapping the spacer structure around the cavity.

4. The device according to claim 1, wherein the film defines a platform that overlaps the cavity and the microelectromechanical system die is coupled to the platform.

5. The device according to claim 4, wherein the cavity is filled with a sealing gel.

6. The device according to claim 1, the platform is suspended by an anchor.

7. The device according to claim 6, wherein the anchor is defined by an anchor portion of the spacer structure.

8. The device according to claim 6, wherein the platform is centrally supported by the anchor.

9. The device according to claim 6, wherein the platform comprises a central anchor portion supported by the anchor, an outer frame and arms projecting from the anchor and connecting the central anchor portion to the outer frame.

10. The device according to claim 6, wherein the platform is supported laterally by the anchor.

11. The device according to claim 6, wherein the film comprises an anchor portion supported by the anchor and at least one arm connecting the anchor portion to the platform.

12. The device according to claim 11, wherein the platform is frame-shaped and wherein an outer side of the platform is connected to the anchor portion of the film by the at least one arm.

13. The device according to claim 1, wherein:
the support structure includes a substrate and a control die, the control die is coupled to the substrate and in electrical communication with the microstructure of the microelectromechanical system die; and
the connection structure couples the microelectromechanical system die to the control die.

14. A method, comprising:
depositing a spacer layer of resist on a semiconductor wafer;
from the spacer layer, forming a spacer structure laterally delimiting at least in part a cavity;
applying a film to the semiconductor wafer, so that it adheres to the spacer structure; and
joining a microelectromechanical system die incorporating a microelectromechanical structure to the film on the cavity.

15. The method according to claim 14, wherein the film is of dry resist and is defined with a photolithographic process before joining the microelectromechanical system die.

16. A device, comprising:
a substrate including a first surface;
a control die on the first surface of the substrate, the control die including a second surface facing away from the substrate;
a suspended support structure suspended over the second surface of the control die, the suspended support structure including an outer frame and one or more openings that are surrounded by the outer frame; and
a microelectromechanical system (MEMS) die coupled to the outer frame of the suspended support structure.

17. The device of claim 16, further comprising an anchor coupled to the suspended support structure and coupled to the second surface of the control die.

18. The device of claim 17, wherein the suspended support structure further includes:
a central anchor portion within the outer frame, the central anchor portion is coupled to the anchor of the suspended support structure;
a plurality of arms that extend from the outer frame to the central anchor portion; and
a plurality of openings delimited by the plurality of arms and the outer frame.

19. The device of claim 16, further comprising an anchor that extends around the outer frame of the suspended support structure, is coupled to the outer frame, and is coupled to the second surface of the control die.
